(19) United States
(12) Patent Application Publication
(10) Pub. No.: US 2008/0135988 A1
(43) Pub. Date: Jun. 12, 2008

(54) Method to reduce semiconductor device leakage

(75) Inventors: Amit Subhash Kelkar, Flower Mound, TX (US); Joshua Li, Plano, TX (US); Danh John C. Nguyen, Southlake, TX (US); Vijay Ullal, Saratoga, CA (US)

Correspondence Address: NORTH WEBER & BAUGH LLP, 2479 E. BAYSHORE ROAD, SUITE 707, PALO ALTO, CA, 94303, US

(73) Assignee: Maxim Integrated Products, Inc.

(21) Appl. No.: 11/636,144

(22) Filed: Dec. 7, 2006

(51) Int. Cl. H01L 29/30; H01L 21/322

(52) U.S. Cl. 257/655; 438/471; 257/E29.107; 257/E21.318

(57) ABSTRACT

Various embodiments of the present invention relate to systems, devices, and methods for treating a semiconductor substrate, such as a silicon wafer, in order to reduce current leakage therein. A semiconductor substrate is provided a plurality of heating treatments that create a denuded zone adjacent to a surface of the substrate and a core zone below the denuded zone. Oxygen impurities within the denuded zone are removed through an oxygen out-diffusion heat treatment. A plurality of macroscopic bulk micro defects is generated within the core zone through the combination of an agglomeration heat treatment and a macroscopic growth heat treatment. This plurality of macroscopic bulk micro defects inhibits migration of metallic contaminants that are located within the substrate. For exemplary purposes, certain embodiments are described relating to a semiconductor wafer heated in a sequence of three treatments. Each treatment has a temperature range in which the substrate is heated and an associated time range during which the treatment occurs.

### BACKGROUND

A. Technical Field

The present invention relates generally to the manufacture of semiconductor devices, and more particularly, to the suppression of leakage current at p-n junctions in such devices.

B. Background of the Invention

Defects within a semiconductor wafer, such as a silicon wafer, may potentially degrade the electrical characteristics of the substrate. These defects may be generated during the manufacturing of the substrate and include metallic impurities, oxygen precipitates and dislocations.

The defects within the wafer can produce leakage current at semiconductor p-n junctions, which oftentimes degrade the performance of devices realized on the substrate. For example, leakage current may generate power dissipation issues, degrade device stability, and cause electrical characteristics to change over time.

As data rates and component densities of devices realized on semiconductor wafers continually increase, the importance of reducing current leakage becomes increasingly apparent. Current leakage can potentially cause semiconductor devices to operate outside of a set specification, or otherwise to fail.

### SUMMARY OF THE INVENTION

Various embodiments of the present invention relate to systems, devices and methods for treating a semiconductor substrate, such as a silicon wafer, in order to reduce current leakage therein. A semiconductor substrate is provided a plurality of heating treatments that create a denuded zone adjacent to a surface of the substrate and a core zone below the denuded zone. Oxygen impurities within the denuded zone are removed through an oxygen out-diffusion heat treatment. A plurality of macroscopic bulk micro defects is generated within the core zone through the combination of an agglomeration heat treatment and a macroscopic growth heat treatment. This plurality of macroscopic bulk micro defects inhibits migration of metallic contaminants that are located within the substrate. For exemplary purposes, certain embodiments are described relating to a semiconductor wafer being successively heated within three treatment sequences. Each treatment sequence has an associated temperature range in which the substrate is heated and time range during which the heat process is applied.

One skilled in the art will recognize that embodiments of the present invention may be applied to substrates other than silicon wafers. Additionally, both temperature ranges and time ranges may be adjusted depending on various factors such as the characteristics of the substrate being treated and a desired purity level achieved after the process has been completed. Furthermore, the number of treatments within the process may also be changed to achieve a particular result.

While certain features and advantages of the invention have been generally described in this summary section, additional features, advantages, and embodiments are presented hereinafter or will become apparent to one of ordinary skill in the art in view of the drawings, specification, and claims hereof. Accordingly, it should be understood that the scope of the invention is not limited by the disclosure presented in this summary section.

### BRIEF DESCRIPTION OF THE DRAWINGS

Reference will be made to embodiments of the invention, examples of aspects of which may be illustrated in the accompanying figures. These figures are intended to be illustrative, not limiting. Although the invention is generally described in the context of these embodiments, it should be understood that the scope of the invention is not limited to the particular embodiments thereof disclosed herein.

FIG. 1 is a diagrammatic cross section of a semiconductor device formed in a surface of a silicon substrate to which teachings of the present invention have not been applied.

FIG. 2 is diagram of temperature and time conditions applicable during a first heat treatment for a silicon substrate conducted according to various embodiments of the present invention.

FIG. 3 is a diagrammatic cross section of a semiconductor device formed in a surface of a silicon substrate that was prepared for the formation of that semiconductor device by being subjected to the first heat treatment in accordance with various embodiments of the invention.

FIG. 4 is an exemplary schematic plot of the variation in oxygen content below the surface of the silicon substrate of FIG. 3.

FIG. 5 is diagram of temperature and time conditions applicable during a second heat treatment for a silicon substrate conducted according to various embodiments of the present invention.

FIG. 6 is a diagram of temperature and time conditions applicable during a third heat treatment for a silicon substrate conducted according to various embodiments of the present invention.

FIG. 7 is a diagrammatic cross section of a silicon substrate after being subjected to a series of heat treatments according to various embodiments of the invention.

### DETAILED DESCRIPTION OF THE PREFERRED EMBODIMENTS

In the following description, for the purpose of explanation, specific details are set forth in order to provide an understanding of the invention. It will be apparent, however, to one skilled in the art that the invention may be practiced without selected of these details. One skilled in the art will recognize that embodiments of the present invention, some of which are described below, may advantageously be incorporated into a number of different devices and systems. Structures and devices shown in block diagram are illustrative of exemplary embodiments of the invention and are included to avoid obscuring the invention. Furthermore, connections between components within the figures are not intended to be limited to direct connections. Rather, such connections components may be modified, reconfigured, or otherwise changed by intermediary components.

Reference herein to “one embodiment” or “an embodiment” of the invention means that a particular feature, structure, characteristic, or function described in connection with the embodiment is included in at least one embodiment of the invention. The use of the phrase “in one embodiment” at various locations in the specification are not necessarily all references to a single embodiment of the invention.

Impurities within a semiconductor substrate are removed by a process in which sequential heating treatments are applied to the substrate. The combination of these heating treatments causes impurities within the substrate to migrate to the surface and leave the semiconductor. According to various embodiments of the invention, these heating treatments effectively address different types of structural impurities or defects within the substrate.

A common type of structural defect is the formation of structural discontinuities, such as crystal originated pit defects and oxygen precipitates, in the substrate near-surface of a semiconductor device. These discontinuities directly induce leakage current across p-n junctions of semiconductor devices formed in the substrate near-surface. Another type of structural defect is incidental deposition on the substrate of metallic contaminants, such as iron, chromium, nickel, or copper. The metallic contaminants may migrate through the matrix of the substrate during subsequent manufacturing toward p-n junctions. Upon arriving at a p-n junction, such metallic contaminants serve as electron-hole regeneration-recombination centers that cause leakage through the p-n junction.

According to various embodiments of the present invention, the sequential heating treatments address both structural discontinuities in the substrate near-surface and the migration of deposited metallic contaminants to p-n junctions in the substrate.

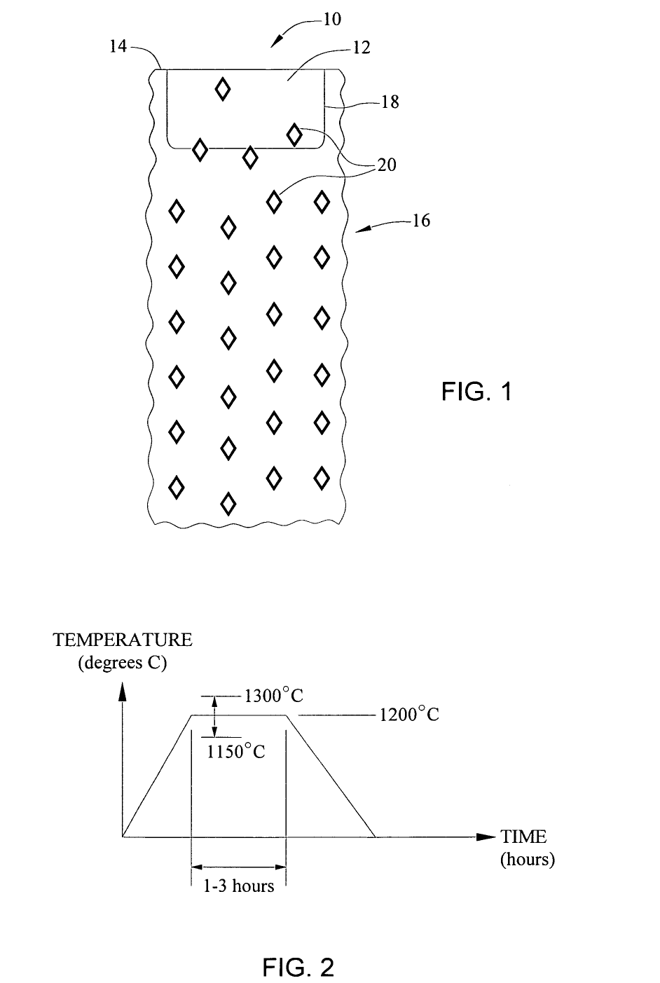

FIG. 1 is a diagrammatic cross section of a semiconductor device 10 having an n-type region 12 that is formed in a surface 14 of a p-type silicon substrate 16. Consequently, semiconductor device 10 includes a p-n junction 18 across which current leakage is routinely a concern.

As teachings of the present invention were not applied to substrate 16 before the manufacture of semiconductor device 10, the entirety of the matrix of substrate 16 is afflicted with structural discontinuities, such as crystal originated pit defects 20 and oxygen precipitates, the later of which are not specifically depicted or referenced in FIG. 1. The presence of crystal originated pit defects 20, particularly in the vicinity of p-n junction 18, has the potential to induce undesirable current leakage at the junction 18. Additionally, metallic contaminants incidentally deposited anywhere on substrate 16, which are not specifically depicted or referenced in FIG. 1, have been free to migrate through the matrix of substrate 16 toward p-n junction 18 during a semiconductor device manufacturing process, collect there and cause current leakage across p-n junction.

To forestall such adverse consequences, according to various embodiments of the present invention, a semiconductor substrate is subjected to a first heat treatment, such as an oxygen out-diffusion heat treatment, the temperature and time conditions of which are depicted diagrammatically in FIG. 2. In one embodiment of the invention, the oxygen out-diffusion heat treatment occurs by subjecting the semiconductor substrate to an inert ambient environment having a temperature range of approximately 1150° to 1300° C. This heat treatment occurs for a time period within the range of approximately one to about three hours.

In another embodiment of the invention, the oxygen out-diffusion heat treatment occurs by subjecting the silicon substrate to an inert ambient environment having a temperature range of approximately 1175° to about 1250° C. This heat treatment occurs for a time period within the range of approximately one to two hours. In yet another embodiment of the invention, the oxygen out-diffusion heat treatment subjects the silicon substrate to an inert ambient environment having a temperature of about 1200° C. for a time period of about one hour.

The oxygen out-diffusion heat treatment dissolves silicon oxide linings of crystal originated pit defects located in a portion of the substrate adjacent to the surface. As a result, oxygen from the crystal originated pit defects is released into the matrix of the substrate and subsequently diffuses entirely out of the substrate. The portion of the substrate thusly purified of crystal originated pit defects then becomes a denuded zone at the surface of the substrate.

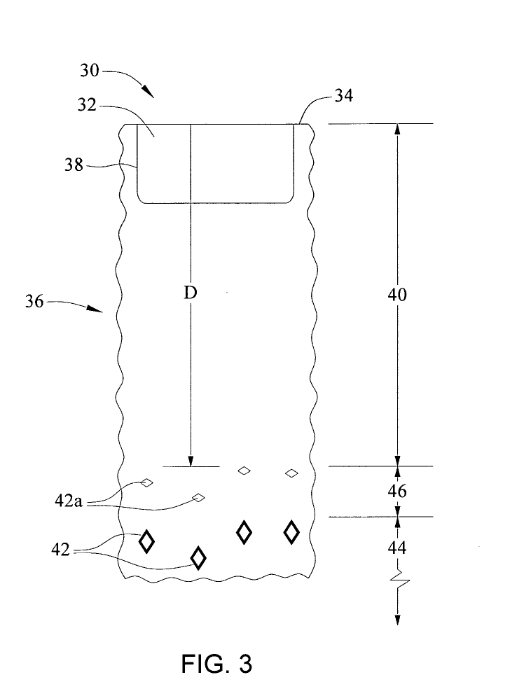

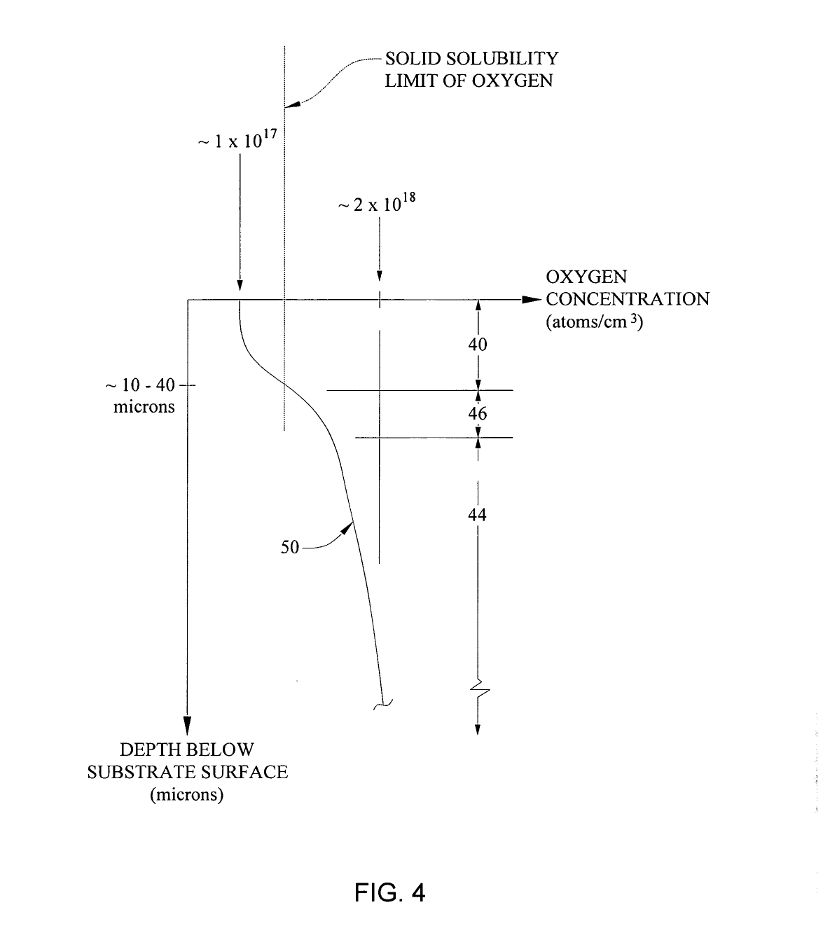

FIG. 3 illustrates an exemplary denuded zone according to various embodiments of the invention. The denuded zone has an improved capacity to of serve as a site for the formation of a p-n junction due to the reduction there of structural discontinuities, such as crystal originated pit defects and oxygen precipitates, which may potentially induce leakage current in the p-n junction.

A semiconductor device 30 is shown having an n-type region 32 that is formed in a surface 34 of a p-type silicon substrate 36. Leakage current across a p-n junction 38 is minimal because the semiconductor device 30 is formed within a denuded zone 40 adjacent to the surface 34 of the substrate 36. The denuded zone 40 was formed prior to the creation of the semiconductor device 30 by subjecting the substrate 36 to the oxygen out-diffusion heat treatment depicted in FIG. 2. Consequently, the denuded zone 40 is free or almost free of crystal originated pit defects 42, while defects remain in the core 44 of the substrate 36 below the denuded zone 40. Between the denuded zone 40 and the core 44 of the substrate 36 is a transition region 46 in which crystal originated pit defects 40a are of a somewhat diminished size.

In general, the denuded zone 40 extends into the substrate 36 from surface 34 thereof for a distance D that is preferably greater than the anticipated depth of any semiconductor device, such as semiconductor device 30, which is ultimately to be formed in the substrate 36. According to certain implementations of the invention, it is recommended that an effective distance D by which the denuded zone 40 extends into substrate 36 be in a range of approximately ten to twenty microns. A distance D in that range results when the oxygen out-diffusion heat treatment of FIG. 2 occurs at a temperature of about 1200° C. for as time period of about one hour. A larger distance D in a range of approximately twenty to forty microns results when the oxygen out-diffusion heat treatment of FIG. 2 occurs at a temperature of about 1200° C. for more than two hours.

FIG. 4 illustrates a plot of oxygen concentration variation in the surface layers of a substrate 36 that has been provided with a denuded zone 40 according to various embodiments of the invention. In the denuded zone 40, plot 50 of oxygen concentration is about 1×10⁷ atoms/cm³, well below the solid solubility limit of oxygen. By contrast, in core 44 of substrate 36, plot 50 of oxygen concentration approaches about 2×10¹⁸ atoms/cm³, which is typical of as-grown silicon wafer substrates. In transition region 46, oxygen concentration assumes an intermediate range of smoothly varying quantities. The conditions depicted in FIG. 4 arise when the oxygen out-diffusion heat treatment of FIG. 2 is conducted at a temperature of about 1200° C. for a time period of about two hours.

The substrate 36 is further processed to combat the effects of subsequent incidental depositions of metallic contaminants, such as iron, chromium, nickel, or copper, which have the potential of increasing leakage current across p-n junctions. During subsequent manufacturing processes, such contaminations would otherwise migrate through the matrix of the substrate 36 toward p-n junctions, collecting there and causing current leakage at those locations.

According to various embodiments of the present invention, the substrate 36 is subjected to second and third heat treatments, which produce bulk micro defects in the core 44 of the substrate 36 below the denuded zone 40. These bulk micro defects act as impurity traps for any metallic contaminants that might migrate through the matrix of substrate 36 toward p-n junctions during subsequent steps required in the formation of semiconductor devices. As the bulk micro defects are developed essentially from oxygen interstitial to the silicon of such substrates, none arise in denuded zone 40.

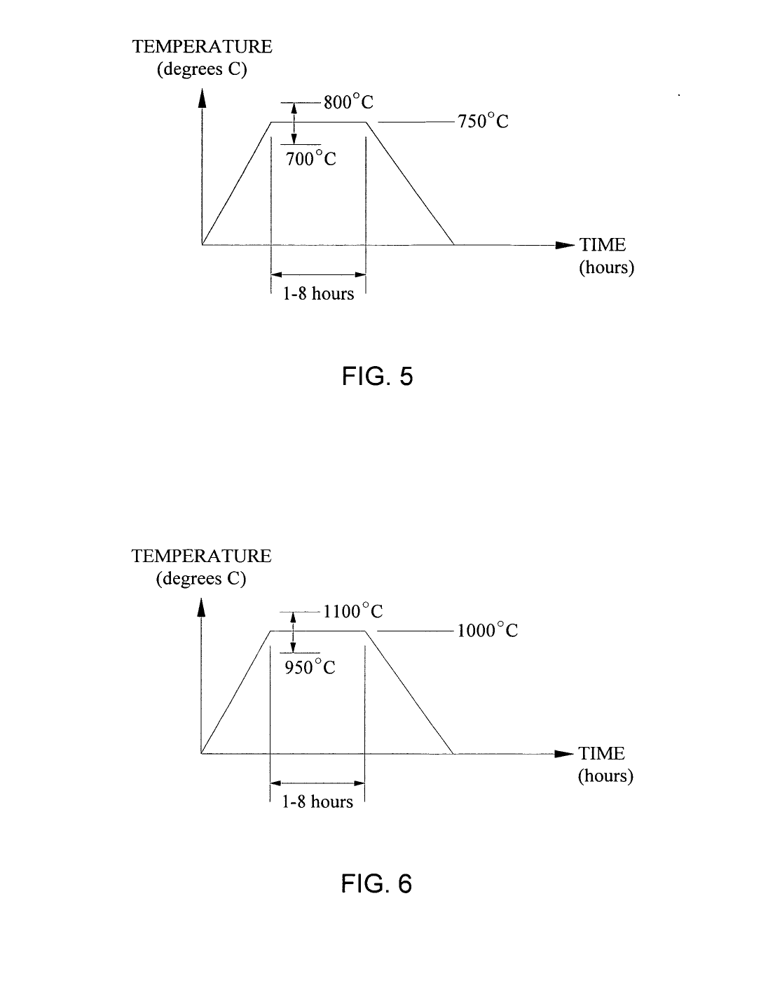

The second heat treatment, an agglomeration heat treatment, is conducted on substrate 36 according to time and temperature constraints depicted diagrammatically in FIG. 5. In various embodiments of the invention, the agglomeration heat treatment occurs by subjecting the substrate 36 to an inert ambient environment having a temperature range of approximately 700° to about 800° C. This heat treatment occurs for a time period within the range of approximately one to eight hours.

In other embodiments of the invention, the agglomeration heat treatment occurs by subjecting the substrate 36 to an inert ambient environment having a temperature range of approximately 725° to about 775° C. This heat treatment occurs for a time period within the range of approximately one to about four hours. Alternatively, the agglomeration heat treatment occurs by subjecting the silicon substrate 36 to an inert ambient environment having a temperature of approximately 750° C. for a time period greater than about one hour.

In the agglomeration heat treatment of FIG. 5, individual atoms of oxygen, trapped within the matrix of the core 44 of the substrate 36, move through the matrix, collecting together into microscopic nuclei of oxygen. Such microscopic nuclei are not per se useful in reducing leakage current in the semiconductor device 30 and cannot be visually detected. Only by a resort to the form into which those microscopic nuclei mature by the processing of substrate 36 through the third heat treatment mentioned above can the earlier presence of such microscopic nuclei be retroactively be verified. Thus, the third heat treatments to which substrate 36 is subjected is a follow up to the second heat treatment, the pair being sequentially bound together toward a single effect, the production of plentiful bulk micro defects in the core 44 of the substrate 36.

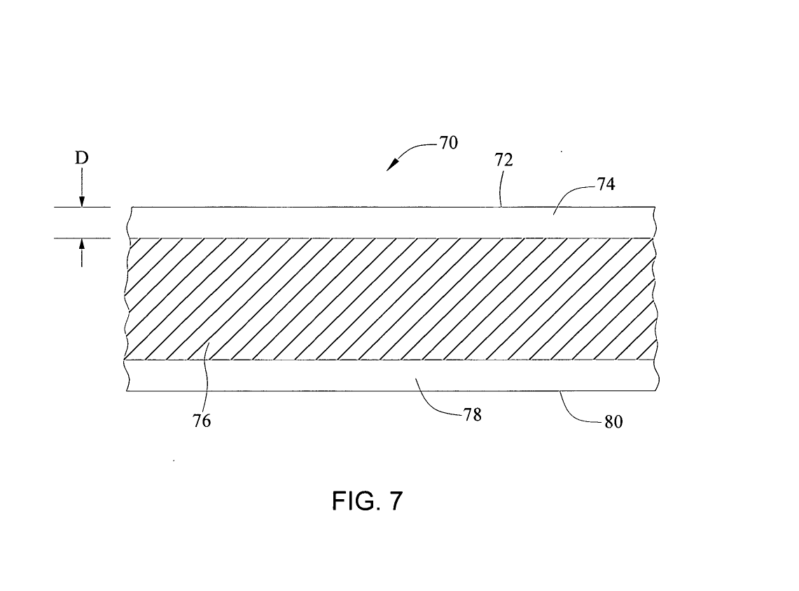

The third heat treatment, a macroscopic growth heat treatment, is one that generally occurs at temperatures higher that those of the second heat treatment. The macroscopic growth heat treatment is conducted on substrate 36 according to time and temperature constraints depicted diagrammatically in FIG. 6. In various embodiments of the invention, the macroscopic growth heat treatment occurs by subjecting the substrate 36 to an inert ambient environment having a temperature range of approximately 950° to about 1150° C. This heat treatment occurs for a time period within the range of approximately one to eight hours.

In other embodiments of the invention, the macroscopic growth heat treatment occurs by subjecting the substrate 36 to an inert ambient environment having a temperature range of approximately 1000° to about 1100° C. This heat treatment occurs for a time period within the range of approximately for one to four hours. Alternatively, the macroscopic growth heat treatment occurs by subjecting the substrate 36 to an inert ambient environment having a temperature of about 1050° C. for a time period of about one hour.

During the macroscopic growth heat treatment, each microscopic nucleus of oxygen formed in the preceding agglomeration heat treatment grows in size by attracting additional oxygen impurities scattered throughout the matrix of the core 44 of the substrate 36. This growth produces from each such microscopic nucleus of oxygen a cluster of silicon oxide that is commonly referred to as a bulk micro defect. The presence of numerous bulk micro defects in the core 44 is advantageous during subsequent semiconductor device manufacturing activities, because bulk micro defects are very attractive to metallic impurities that might be migrating through the substrate 36 toward p-n junctions. Metallic impurities that reach a bulk micro defect become immobilized in the bulk micro defect.

One skilled in the art will recognize that variations to the above described sequence of heating treatments may be provided in order to achieve different or preferred results. Further, the heating treatments may further be supplemented with additional purifying stages in which the characteristic improvements of the substrate are realized.

FIG. 7 is a diagrammatic cross section of a silicon substrate 70 having been subjected to the three heating treatments described above. Substrate 70 is in a preferred condition for the formation of semiconductor devices in the near-surface 72 thereof. A denuded zone 74 is located adjacent to the near-surface 72 and extending for a distance D into substrate 70 greater than any anticipated semiconductor device to be created in substrate 70. As previously described, this denuded zone 74 is substantially free of crystal originated pit defects.

Below the denuded zone 74, the core 76 of substrate 70 includes an abundance of bulk micro defects of the type that trap migrating metallic contaminants. Core 76 thus serves to scour the matrix of substrate 70 of metallic impurities as semiconductor device formation procedures ensue. Inherently, a lower denuded zone 78 arises adjacent to the lower side 80 of the substrate 70 during the first heat treatment. Generally, semiconductor devices are not formed in the lower denuded zone 80, although any such semiconductor devices would also benefit from minimized leakage current in the manner of semiconductor devices formed in denuded zone 74 at the near-surface 72.

The foregoing description of the invention has been described for purposes of clarity and understanding. It is not intended to limit the invention to the precise form disclosed. Various modifications may be possible within the scope and equivalence of the appended claims.

1. A method for removing and preventing migration of defects within a semiconductor substrate, the method comprising:
applying a first treatment to the substrate by heating the substrate within a first temperature range for a first time period, the first treatment causing a denuded zone to form within the substrate;
applying a second treatment to the substrate by heating the substrate within a second temperature range for a second time period, the second treatment causing a plurality of microscopic nuclei of oxygen to form below the denuded zone in a core of the substrate; and
applying a third treatment to the substrate by heating the substrate within a third temperature range for a third time period, the third treatment causing the plurality of oxygen nuclei to cluster into a plurality of macroscopic bulk micro defects.

2. The method of claim 1 wherein the first temperature range is approximately 1150° to 1300° C., and the first time period is approximately one to three hours.

3. The method of claim 1 wherein the first temperature range is approximately 1175° to about 1250° C., and the first time period is approximately one to two hours.

4. The method of claim 1 wherein the first temperature range is approximately 1200° C., and the first time period is approximately one hour.

5. The method of claim 1 wherein the denuded zone extends into the substrate from a surface thereof for a distance in a range of approximately ten to forty microns.

6. The method of claim 5 wherein the denuded zone extends into the substrate from the surface thereof for a distance in a range of approximately ten to twenty microns.

7. The method of claim 1 wherein the surface concentration of oxygen in the denuded zone is less than 2×10¹⁸ atoms/cm³.

8. The method of claim 1 wherein the semiconductor substrate is a silicon wafer.

9. The method of claim 1 wherein the second temperature range is approximately 7000 to about 800° C., and the second time period is approximately one to eight hours.

10. The method of claim 1 wherein the second temperature range is approximately 725° to about 775° C., and the second time period is approximately one to four hours.

11. The method of claim 1 wherein the second temperature range is approximately 750° C., and the second time period is greater than one hour.

12. The method of claim 1 wherein the third temperature range is approximately 950° to about 1150° C., and the third time period is approximately one to eight hours.

13. The method of claim 1 wherein the third temperature range is approximately 1000° to about 1100° C., and the third time period is approximately one to four hours.

14. The method of claim 1 wherein the third temperature range is approximately 1050° C., and the third time period is approximately one hour.

15. A method for reducing current leakage in a semiconductor device formed on a substrate, the method comprising:
forming a denuded zone in the substrate at a surface thereof, the denuded zone having a surface concentration of oxygen less than about 2×10¹⁸ atoms/cm³ and extending into the substrate from the surface thereof for a distance greater than the anticipated depth of the semiconductor device;
growing bulk micro defects below the denuded zone in a core of the substrate after the step of forming the denuded zone, the step of growing bulk micro defects comprising the steps of:
(i) subjecting the substrate to an agglomeration heat treatment wherein microscopic nuclei of oxygen form below the denuded zone in the core of the substrate; and
(ii) subjecting the substrate to a macroscopic growth heat treatment after the step of subjecting the substrate to the agglomeration heat treatment, the microscopic nuclei of oxygen thereby growing to macroscopic dimensions into bulk micro defects; and
manufacturing the semiconductor device in the denuded zone after the step of growing bulk micro defects.

16. The method of claim 15 wherein the step of forming the denuded zone comprises the step of subjecting the substrate to an oxygen out-diffusion heat treatment at a temperature of about 1200° C. for a time period of about one hour.

17. The method of claim 15 wherein the step of subjecting the substrate to the agglomeration heat treatment comprises the step of maintaining the substrate at a temperature of about 750° C. for a time period greater than about one hour.

18. The method of claim 15 wherein the step of subjecting the substrate to the macroscopic growth heat treatment comprises the step of maintaining the substrate at a temperature of about 1050° C. for a time period of about one hour.

19. A semiconductor substrate comprising:
a denuded zone located adjacent to a surface of the substrate and having a depth sufficient to allow a semiconductor device to be manufactured within the denuded zone, the denuded zone having a reduced number of crystal originated pit defects resulting from an oxygen evaporation heat treatment; and
a core located within the substrate and below the denuded zone, the core having a plurality of macroscopic bulk micro defects generated by a combination of an agglomeration heat treatment and a macroscopic growth heat treatment.

20. The semiconductor substrate of claim 19 wherein the denuded zone has a surface concentration of oxygen less than about 2×10¹⁸ atoms/cm³.

21. The semiconductor substrate of claim 19 wherein the denuded zone has a depth greater than manufacturing depth of a semiconductor device realized on the substrate.

22. The semiconductor substrate of claim 19 wherein the semiconductor substrate is a silicon wafer.

23. The semiconductor substrate of claim 19 wherein the plurality of macroscopic bulk micro defects improves the substrate metallic gettering efficiency by prohibiting migration of metallic impurities within the substrate.
